(19) United States
(12) Patent Application Publication
(10) Pub. No.: US 2012/0268941 A1
(43) Pub. Date: Oct. 25, 2012

(54) Light Emitting Diode Lamp and Assembling Method Thereof

(75) Inventors: Li-Wei Shih, New Taipei City (TW); Feng-Ting Hsu, New Taipei City (TW)

(73) Assignee: EVERLIGHT ELECTRONICS CO., LTD., New Taipei City (TW)

(21) Appl. No.: 13/450,366

(22) Filed: Apr. 18, 2012

(30) Foreign Application Priority Data
Apr. 19, 2011 (TW) 100113600

(51) Int. Cl. F21V 29/00; H05K 13/00; F21V 1/00

(52) U.S. Cl. 362/294; 362/382; 29/592.1

(57) ABSTRACT

A light emitting diode lamp according to an embodiment of the present disclosure includes a heat dissipation structure, a light emitting diode (LED) light source and a driver. The LED light source is thermally disposed over and electrically insulated from the heat dissipation structure. The LED light source includes at least one lateral surface on which an electrode is disposed. The driver is disposed under and electrically insulated from the heat dissipation structure. The driver includes an extended portion that is electrically coupled to the electrode by penetrating through the heat dissipation structure.

### CROSS-REFERENCE TO RELATED APPLICATION

This application claims the priority benefit of Taiwan Patent Application No. 100113600, filed on Apr. 19, 2011. The entirety of the above-mentioned patent application is hereby incorporated by reference and made a part of this specification.

### BACKGROUND

1. Technical Field

The present invention relates to a lamp and assembling method thereof and, more particularly, to a light emitting diode (LED) lamp and assembling method thereof.

2. Description of Related Art

LEDs are semiconductor components the light-emitting chip of which is primarily made of compounds of chemical elements of the III-V groups such as GaP or GaAs, for example. The principle of light emission of LEDs involves the conversion of electrical energy into photonic energy. More specifically, when an electrical current is applied through the compound semiconductor of an LED, the combination of electrons and holes releases excess energy in the form of light emission. The useful life of LEDs is typically more than 100,000 hours since light emission by LEDs is not due to heating or electrical discharge. Moreover, LEDs have the advantages of fast response, compact size, low power consumption, low pollution, high reliability and suitability for mass production. Accordingly, there exists a wide range of applications of LEDs, including being the light source of large billboards, traffic signals, mobile phones, scanners, facsimile machines, LED lamps, etc.

With respect to LED lamps, one way to avoid overheating of the LED light source due to light emission is to dispose the LED light source on a heat dissipation structure to dissipate heat from the LED light source through the heat dissipation structure. Such heat dissipation structure is typically made of a metallic material with good thermal conductivity. Under the existing technology, an LED light source is disposed on a substrate which is disposed on a heat dissipation structure such that the substrate prevents electrical coupling between the LED light source and the heat dissipation structure that would cause malfunction. However, although the substrate may prevent electrical coupling between the LED light source and the heat dissipation structure, the substrate nevertheless lowers the efficiency in heat dissipation as it hinders heat transfer from the LED light source to the heat dissipation structure. In addition, as the LED light source is typically electrically coupled to a driver circuit of the lamp through conductive wires, configuration of the conductive wires generally increases the difficulty and cost in assembly.

### SUMMARY

The present invention provides an LED lamp having better heat dissipation efficiency and lower manufacturing cost.

The present invention further provides an assembling method of an LED lamp that reduces the difficulty and time in assembling, thereby lowering manufacturing cost.

According to one aspect, an LED lamp may comprise a heat dissipation structure, an LED light source, and a driver. The LED light source may be disposed over and electrically insulated from the heat dissipation structure. The LED light source may include at least a side having an electrode. The driver may be disposed under and electrically insulated from the heat dissipation structure. The driver may include at least an extended portion that is electrically coupled to the electrode by penetrating through the heat dissipation structure.

In one embodiment, the heat dissipation structure may include at least one opening. The extended portion of the driver may penetrate through the at least one opening and extends toward the LED light source to be electrically coupled to the electrode.

In one embodiment, the heat dissipation structure may include a reception slot in which the LED light source is disposed.

In one embodiment, the LED lamp may further comprise a lampshade. The lampshade and the heat dissipation structure may include at least one positioning slot and at least one positioning rib respectively received in the at least one positioning slot when the lampshade is assembled to the heat dissipation structure to cover the LED light source.

In one embodiment, the LED lamp may further comprise a shell. The shell and the heat dissipation structure may include at least one positioning rib and at least one positioning slot in which the at least one positioning rib is respectively received.

In one embodiment, the LED lamp may further comprise a shell that includes at least one positioning slot. The driver may include a circuit board having one or more edges respectively received in the at least one positioning slot of the shell. Optionally, the driver may further comprise at least one terminal that is electrically coupled to the circuit board and not coplanar with the circuit board. In one embodiment, the circuit board may be electrically coupled to the extended portion of the driver, and the shell may include at least one opening through which the at least one terminal penetrates the shell.

According to another aspect, an LED lamp may comprise a heat dissipation structure, an LED light source, a shell, and a driver. The heat dissipation structure may include a plurality of openings. The LED light source may be coupled to the heat dissipation structure and may include a plurality of electrodes. The shell may be assembled to the heat dissipation structure. The driver may be disposed in the shell and may include a plurality of extended portions. The LED light source and the driver may be disposed on two opposing sides of the heat dissipation structure. The plurality of extended portions may respectively penetrate through the plurality of openings such that the extended portions extend toward the LED light source and are electrically coupled to the electrodes.

In one embodiment, the heat dissipation structure may include a surface and a protrusion connected to the surface. The LED light source may include a bottom surface that comprises a central portion and a peripheral portion such that the central portion is in contact with the protrusion and that the electrodes are disposed on the peripheral portion and spaced apart from the surface of the heat dissipation structure.

In one embodiment, the heat dissipation structure may include a reception slot in which the LED light source is disposed.

In one embodiment, the LED lamp may further comprise a lampshade that includes at least one positioning slot. The heat dissipation structure may include at least one positioning rib respective received in the at least one positioning slot of the lampshade such that the lampshade is assembled to the heat dissipation structure to cover the LED light source.

In one embodiment, the shell may include at least one positioning rib and the heat dissipation structure may include at least one positioning slot respectively receiving the at least one positioning rib of the shell.

In one embodiment, the shell may include at least one positioning slot, and the driver may include a circuit board having one or more edges respectively received in the at least one positioning slot of the shell. Optionally, the driver may further include a plurality of terminals that are electrically coupled to and not coplanar with the circuit board. The circuit board may be electrically coupled to at least some of the extended portions. The shell may include a plurality of openings such that the terminals extend out of the shell through the openings of the shell.

According to a further aspect, a method of assembling an LED lamp may comprise: providing a heat dissipation structure that includes a plurality of openings, a surface, and a protrusion connected to the surface; providing an LED light source that includes a bottom surface and a plurality of electrodes, the bottom surface comprising a central portion and a peripheral portion with the electrodes disposed on the peripheral portion; connecting the central portion of the LED light source to the protrusion of the heat dissipation structure such that the electrodes are spaced apart from the surface of the heat dissipation structure; providing a shell; disposing a driver, that includes a plurality of extended portions, inside the shell; and assembling the shell to the heat dissipation structure such that: the LED light source and the driver are disposed on two opposing sides of the heat dissipation structure, and the extended portions are electrically coupled to the electrodes of the LED light source by penetrating through the openings of the heat dissipation structure.

In one embodiment, the method may further comprise: providing a lampshade; and assembling the lampshade to the heat dissipation structure such that the lampshade covers the LED light source.

In one embodiment, the heat dissipation structure may include at least one positioning rib, and the lampshade may include at least one positioning slot. Assembling the lampshade to the heat dissipation structure may comprise the at least one positioning slot of the lampshade respectively receiving the at least one positioning rib of the heat dissipation structure when the lampshade is assembled to the heat dissipation structure.

In one embodiment, the shell may include at least one positioning rib, and the heat dissipation structure may include at least one positioning slot. Assembling the shell to the heat dissipation structure may comprise the at least one positioning slot of the heat dissipation structure respectively receiving the at least one positioning rib of the shell when the shell is assembled to the heat dissipation structure.

In one embodiment, the shell may include at least one positioning slot, and the driver may include a circuit board. Disposing the driver inside the shell may comprise respectively receiving one or more edges of the circuit board of the driver in the at least one positioning slot of the shell. Optionally, the driver may further include a plurality of terminals that are electrically coupled to and not coplanar with the circuit board. In one embodiment, the circuit board may be electrically coupled to the extended portions. The shell may include a plurality of openings. Disposing the driver inside the shell may comprise extending the terminals out of the shell through the openings of the shell.

Accordingly, the heat dissipation structure according to an embodiment of the present invention includes a protrusion with the LED light source disposed on the protrusion, so that electrodes of the LED light source are spaced apart from a surface of the heat dissipation structure. Consequently, there is no need to configure a substrate between the LED light source and the heat dissipation structure in order to avoid electrical conduction between the LED light source and the heat dissipation structure. Advantageously, this feature reduces the number of components and lowers manufacturing cost. Additionally, heat dissipation efficiency is improved with the central portion of the bottom surface of the LED light source in direct contact with the heat dissipation structure. Moreover, as the extended portions penetrate through the openings and extend toward the LED light source to be respectively electrically coupled to the electrodes of the LED light source, there is no need for conductive wires to electrically couple the LED light source to the driver. This feature advantageously simplifies the manufacturing process and improves the production efficiency.

To facilitate better understanding of the features of and benefits provided by the present invention, implementation examples are provided in the Detailed Description section below with reference to the accompanying drawings.

### BRIEF DESCRIPTION OF THE DRAWINGS

FIG. 1 is a side view of an LED lamp in accordance with an embodiment of the present invention.

FIG. 2 is an exploded view of the LED lamp of FIG. 1.

FIG. 3 is a cross-sectional view of a portion of the LED lamp of FIG. 1.

FIG. 4 is a partial side view of a driver of FIG. 2.

FIGS. 5A-5C show a process of assembling the LED lamp of FIG. 1.

FIG. 6 is a flowchart of an assembling method for the LED lamp of FIG. 1.

### DETAILED DESCRIPTION OF PREFERRED EMBODIMENTS

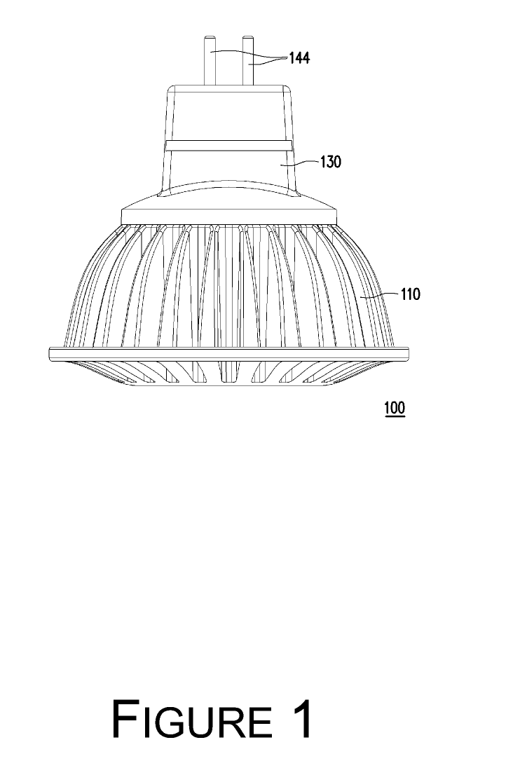

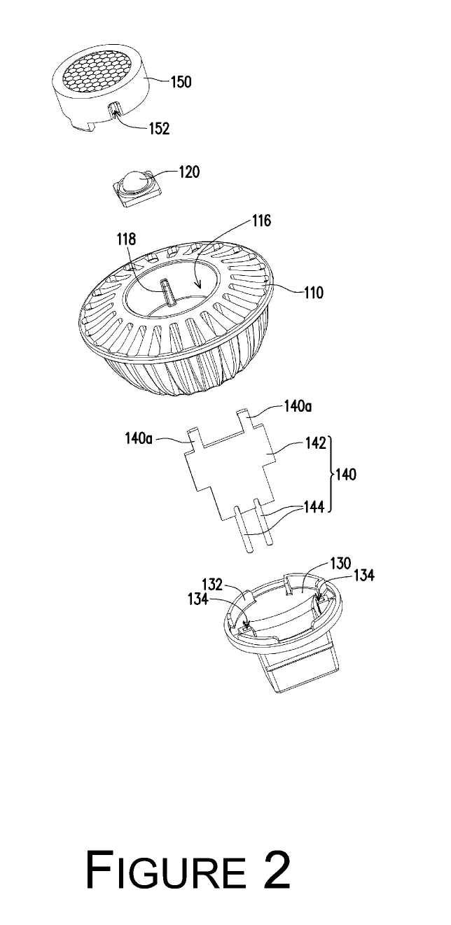

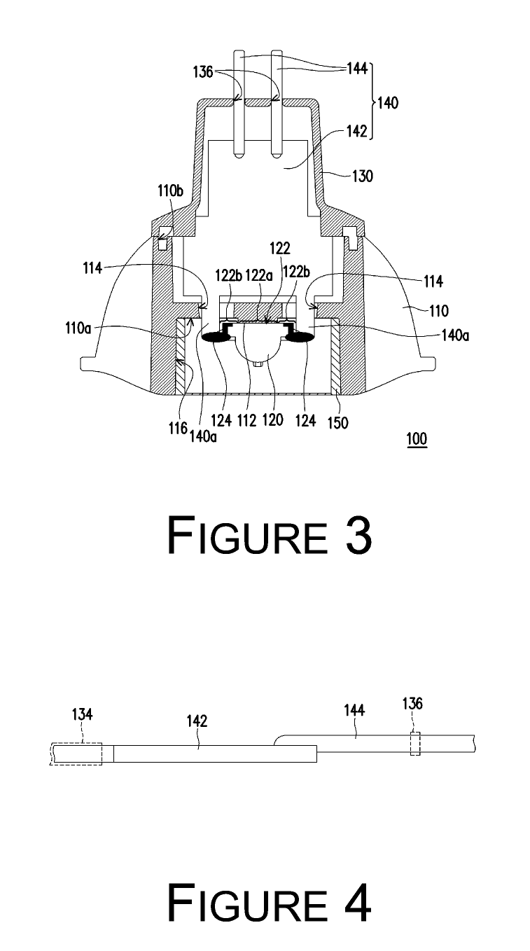

FIG. 1 illustrates a side view of an LED lamp in accordance with an embodiment of the present invention. FIG. 2 illustrates an exploded view of the LED lamp of FIG. 1. FIG. 3 illustrates a cross-sectional view of a portion of the LED lamp of FIG. 1. Referring to FIGS. 1-3, in one embodiment, an LED lamp 100 comprises a heat dissipation structure 110, an LED light source 120, a shell 130 and a driver 140. The LED light source 120 is thermal-conductively disposed over the heat dissipation structure 110, and is electrically insulated from the heat dissipation structure 110. The LED light source 120 has at least one side that includes an electrode 124. The driver 140 is disposed under the heat dissipation structure 110, and is electrically insulated from the heat dissipation structure 110. The driver 140 includes at least an extended portion 140a. The extended portion 140a penetrates through the heat dissipation structure 110 and is electrically coupled to the electrode 124.

In the illustrated embodiment, the heat dissipation structure 110 includes a surface 110a and a protrusion 112 that is connected to the surface 110a. The LED light source 120 includes a bottom surface 122 and a plurality of electrodes 124. The bottom surface 122 comprises a central portion 122a and a peripheral portion 122b around the central portion 112a. The central portion 122a is in contact with or otherwise connected to the protrusion 112. The electrodes 124 are disposed on the peripheral portion 122b and are spaced apart from the surface 110a of the heat dissipation structure 110. One or more of the electrodes 124 may extend from the peripheral portion 122b to one or more sides of the LED light source 120. The shell 130 is assembled to the heat dissipation structure 110. The driver 140 is disposed inside the shell 130 and is electrically coupled to the electrodes 124 of the LED light source 120 to drive the LED light source 120 to emit light.

In the illustrated embodiment, the LED light source 120 is electrically insulated from the heat dissipation structure 110. The driver 140 is electrically insulated from the heat dissipation structure 110 and the shell 130. In one embodiment, the LED light source 120 may comprise a single-crystal or poly-crystal package structure. Alternatively, the LED light source 120 may comprise a chip-on-board (COB) package structure. Alternatively, the LED light source 120 may comprise a LED chip of a single color or multiple colors. Furthermore, the LED light source 120 may include fluorescent powder of a single color or multiple colors. Moreover, the LED lamp 100 may comprise an LED bulb of type A (e.g., A60), type GU (e.g., GU-10), type PAR (e.g., PAR-30), or type MR (e.g., MR-16).

In the above-described configuration, the electrodes 124 of the LED light source 120 are spaced apart from, and thus not in contact with, the surface 110a of the heat dissipation structure 110. Accordingly, there is no need to configure a substrate between the LED light source 120 and the heat dissipation structure 110 in order to avoid electrical conduction between the LED light source 120 and the heat dissipation structure 110. Advantageously, this feature reduces the number of components and lowers manufacturing cost. Additionally, heat dissipation efficiency is improved with the central portion 122a of the bottom surface 122 of the LED light source 120 in direct contact with the heat dissipation structure 110. The central portion 122a of the heat dissipation structure 110 may be, for example, welded or bonded to the heat dissipation structure 110.

In addition, in the illustrated embodiment, the LED light source 120 and the driver 140 are respectively disposed on two opposing sides of the heat dissipation structure 110. The heat dissipation structure 110 has a plurality of openings 114 (two of which are shown), and the driver 140 has a plurality of extended portions 140a (two of which are shown). As shown in FIG. 3, the extended portions 140a penetrate through the openings 114 and extend toward the LED light source 120 and are respectively electrically coupled to the electrodes 124. Each of the extended portions 140a may be electrically coupled to a respective one of the electrodes 124 by, for example, welding. Accordingly, no conductive wire is needed to electrically couple the LED light source 120 and the driver 140. The manufacturing process is thereby simplified, advantageously resulting in improved production efficiency.

Referring to FIGS. 2 and 3, the heat dissipation structure 110 includes a reception slot 116 in which the LED light source 120 is disposed. The LED lamp 100 further comprises a lampshade 150 that is assembled to the heat dissipation structure 110 and covers the LED light source 120. In one embodiment, each of the lampshade 150 and the shell 130 may be glued or engaged, or otherwise fastened, to be affixed to the heat dissipation structure 110 to avoid the use of screws or nuts and bolts for assembling, thereby further simplifying the manufacturing process.

Referring to FIG. 2, in one embodiment, the heat dissipation structure 110 includes at least one positioning rib 118, and the lampshade 150 includes at least one positioning slot 152. Alternatively, the heat dissipation structure 110 may include at least one positioning slot, and the lampshade 150 may include at least one positioning rib. In one embodiment, between the heat dissipation structure 110 and the lampshade 150 there exist at least one positioning rib and at least one positioning slot in correspondence with the engagement design. When the lampshade 150 is assembled to the heat dissipation structure 110, the positioning rib 118 is received in the positioning slot 152 to firmly affix the lampshade 150 and the heat dissipation structure 110 in their relative positions. Moreover, in one embodiment, the shell 130 includes at least one positioning rib 132, and the heat dissipation structure includes at least one positioning slot 110b (as shown in FIG. 3). Alternatively, the shell 130 may include at least one positioning slot, and the heat dissipation structure 110 may include at least one positioning rib. Between the shell 130 and the heat dissipation structure 110 there exist at least one positioning rib and at least one positioning slot in correspondence with the engagement design. When the shell 130 is assembled to the heat dissipation structure 110, the positioning rib 132 is received in the positioning slot 110b to firmly affix the shell 130 and the heat dissipation structure 110 in their relative positions.

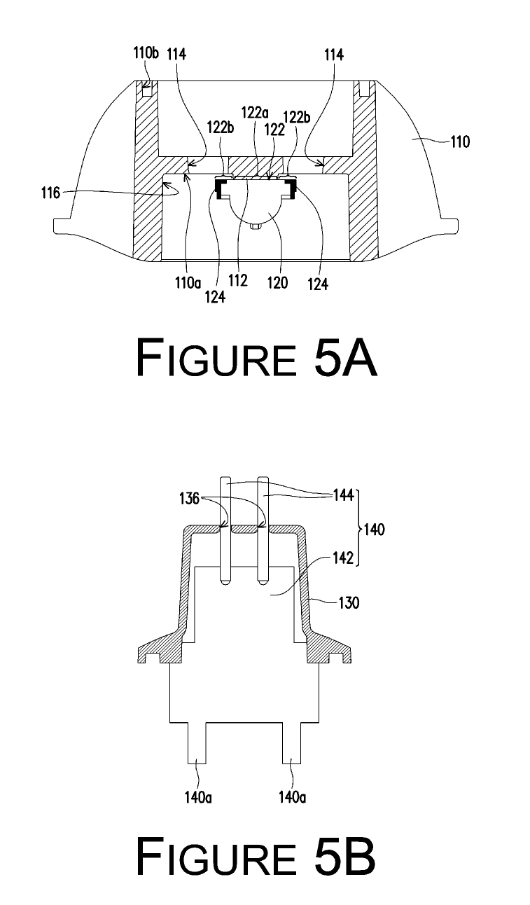

Referring to FIGS. 2 and 3, in one embodiment, the shell 130 includes at least one positioning slot 134 and a plurality of openings 136. The driver 140 includes a circuit board 142 and a plurality of terminals 144. The circuit board 142 is respectively electrically coupled to the terminals 144 and the extended portions 140a. When the driver 140 is disposed inside the shell 130, one or more edges of the circuit board 142 are respectively received in the at least one positioning slot 134. The terminals 144 are respectively electrically coupled to an external electrical power source through the openings 136 of the shell 130. FIG. 4 illustrates a partial side view of the driver 140 of FIG. 2, which is also a partial left side view of the driver 140 of FIG. 3. In one embodiment, as shown in FIG. 4, the terminals 144 are not coplanar with the circuit board 142. When a user inserts the circuit board 142 into the positioning slot 134 of the shell 130 in a correct direction, the terminals 144 will be positioned to align with the openings 136 to protrude out of the shell 130. When the user turns the driver 140 of FIG. 4 upside down by 180 degrees and inserts the circuit board 142 into the positioning slot 134 of the shell 130 in an incorrect direction, the terminals 144 will not be positioned to align with the openings 136 and thus cannot protrude out of the shell 130. This feature advantageously prevents the driver 140 from being inserted into the shell 130 in an incorrect direction during assembly, and hence ensures each of the extended portions 140a is respectively aligned with a correct one of the electrodes 124.

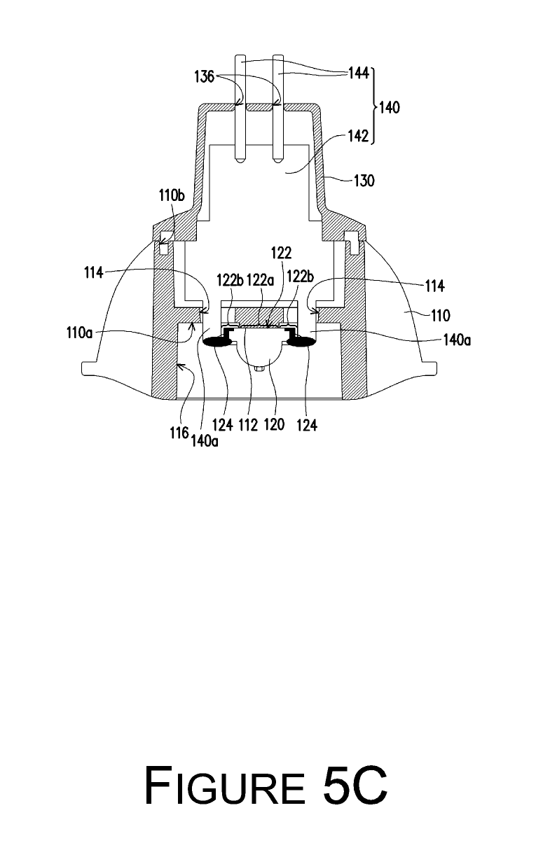

Turning now to the assembling method of the LED lamp 100 of FIG. 1, FIGS. 5A-5C illustrate a process of an assembling method of the LED lamp 100. Referring to FIG. 5A, the heat dissipation structure 110 and the LED light source 120 are provided with the LED light source 120 disposed over the heat dissipation structure 110. The heat dissipation structure 110 includes a plurality of openings 114, a surface 110a and a protrusion 112 connected to the surface 110a. The LED light source 120 includes a bottom surface 122 and a plurality of electrodes 124. The bottom surface 122 includes a central portion 122a and a peripheral portion 122b. The electrodes 124 are disposed on the peripheral portion 122b. When the LED light source 120 is disposed over the heat dissipation structure 110, the central portion 122a of the bottom surface 122 of the LED light source 120 is in contact with or otherwise connected to the protrusion 112 of the heat dissipation structure 110 to cause the electrodes 124 to be spaced apart from the surface 110a of the heat dissipation structure 110. The central portion 122a of the bottom surface 122 of the LED light source 120 may be connected to the protrusion 112 of the heat dissipation structure 110 by, for example, welding or bonding.

Referring to FIG. 5B, the shell 130 and the driver 140 are provided with the driver 140 disposed in the shell 130. The driver 140 includes a plurality of extended portions 140a. Referring to FIG. 5C, after the central portion 122a is connected to the protrusion 112 as shown in FIG. 5A and after the driver 140 is disposed in the shell 130 as shown in FIG. 5B, the shell 130 is assembled to the heat dissipation structure 110 with the LED light source 120 and the driver 140 respectively disposed on two opposing sides of the heat dissipation structure 110. The extended portions 140a penetrate through the openings 114 and extend toward the LED light source 120 and are respectively electrically coupled to the electrodes 124. Each of the extended portions 140a may be electrically coupled to a respective one of the electrodes 124 by, for example, welding.

As electrical conduction is achieved by having the extended portions 140a penetrate through the openings 114 and extend toward the LED light source 120 to be respectively electrically coupled to the electrodes 124 of the LED light source 120, there is no need for conductive wires to electrically couple the LED light source 120 to the driver 140. This feature advantageously simplifies the manufacturing process and improves the production efficiency. Notably, in various embodiments the order of assembling is not limited to that shown in FIGS. 5A and 5B. For example, a process may assemble the LED light source 120 to the heat dissipation structure 110 according to FIG. 5A, then assemble the driver 140 to the shell 130 according to FIG. 5B, and then assemble the shell 130 to the heat dissipation structure 110 according to FIG. 5C. Alternatively, a process may assemble the driver 140 to the shell 130 according to FIG. 5B, then assemble the LED light source 120 to the heat dissipation structure 110 according to FIG. 5A, and then assemble the shell 130 to the heat dissipation structure 110 according to FIG. 5C. Still alternatively, a process may simultaneously assemble the LED light source 120 to the heat dissipation structure 110 according to FIG. 5A and assemble the driver 140 to the shell 130 according to FIG. 5B, and then assemble the shell 130 to the heat dissipation structure 110 according to FIG. 5C to thereby save some assembling time.

The above-described assembling method of the LED lamp 100 may further include providing the lampshade 150 as shown in FIG. 2, and assemble the lampshade 150 to the heat dissipation structure 110 to cover the LED light source 120 according to FIG. 3. In one embodiment, the lampshade 150 may be, for example, glued or engaged, or otherwise fastened, to the heat dissipation structure 110 to avoid the use of screws or nuts and bolts for assembling, thereby further simplifying the manufacturing process.

More specifically, when assembling the lampshade 150 to the heat dissipation structure 110, the positioning rib 118 of the heat dissipation structure 110 (as shown in FIG. 2) is received in the positioning slot 152 of the lampshade 150 (as shown in FIG. 2) to firmly affix the lampshade 150 and the heat dissipation structure 110 in their relative positions. When assembling the shell 130 to the heat dissipation structure 110, the positioning rib 132 of the shell 130 (as shown in FIG. 2) is received in the positioning slot 110b of the heat dissipation structure 110 (as shown in FIG. 3) to firmly affix the shell 130 and the heat dissipation structure 110 in their relative positions.

In addition, when the driver 140 is disposed in the shell 130 as shown in FIG. 5B, one or more edges of the circuit board 142 are respectively received in the at least one positioning slot 134 of the shell 130 (as shown in FIG. 2). The terminals 144 are respectively electrically coupled to an external electrical power source through the openings 136 of the shell 130.

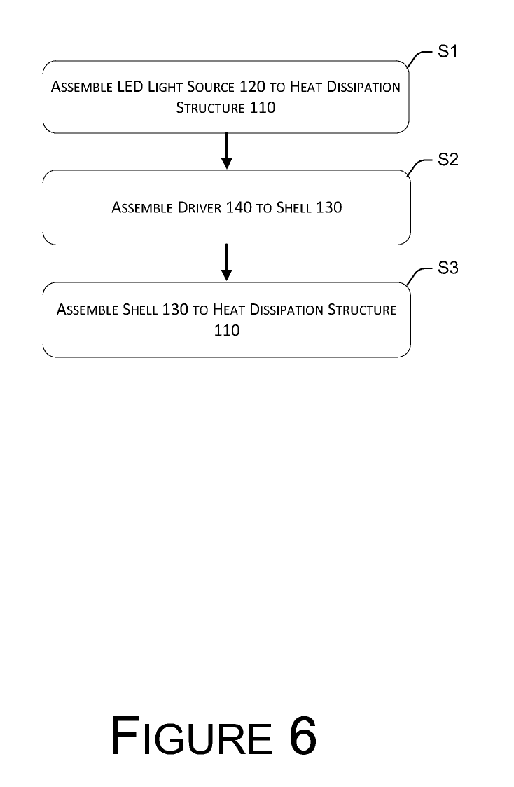

FIG. 6 illustrates a flowchart of an assembling method of the LED lamp 100 of FIG. 1 as well as the process shown in FIGS. 5A-5C. Referring to FIG. 6, at first the LED light source 120 is assembled to the heat dissipation structure 110 (step S1). Next, the driver 140 is assembled to the shell 130 (step S2). Lastly, the shell 130, having the driver 140 disposed therein, is assembled to the heat dissipation structure 110 (step S3). Embodiments of the present invention are not limited to the above-described order with respect to steps S1 and S2. For example, step S2 may be performed before step S1. Alternatively, step S2 may be performed simultaneously with step S1.

In summary, the heat dissipation structure according to an embodiment of the present invention includes a protrusion with the LED light source disposed on the protrusion, so that electrodes of the LED light source are spaced apart from a surface of the heat dissipation structure. Consequently, there is no need to configure a substrate between the LED light source and the heat dissipation structure in order to avoid electrical conduction between the LED light source and the heat dissipation structure. Advantageously, this feature reduces the number of components and lowers manufacturing cost. Additionally, heat dissipation efficiency is improved with the central portion of the bottom surface of the LED light source in direct contact with the heat dissipation structure. Moreover, as the extended portions penetrate through the openings and extend toward the LED light source to be respectively electrically coupled to the electrodes of the LED light source, there is no need for conductive wires to electrically couple the LED light source to the driver. This feature advantageously simplifies the manufacturing process and improves the production efficiency.

Although specific embodiments of the present invention have been disclosed, it will be understood by those of ordinary skill in the art that the foregoing and other variations in form and details may be made therein without departing from the spirit and the scope of the present invention. The scope of the present invention is defined by the claims provided herein.

What is claimed is:

1. A light emitting diode (LED) lamp, comprising:
a heat dissipation structure;
an LED light source disposed over and electrically insulated from the heat dissipation structure, the LED light source including at least a side having an electrode; and
a driver disposed under and electrically insulated from the heat dissipation structure, the driver including at least an extended portion that is electrically coupled to the electrode by penetrating through the heat dissipation structure.

2. The LED lamp as recited in claim 1, wherein the heat dissipation structure includes at least one opening, and wherein the extended portion of the driver penetrates through the at least one opening and extends toward the LED light source to be electrically coupled to the electrode.

3. The LED lamp as recited in claim 1, wherein the heat dissipation structure includes a reception slot in which the LED light source is disposed.

4. The LED lamp as recited in claim 1, further comprising:
a lampshade, wherein the lampshade and the heat dissipation structure include at least one positioning slot and at least one positioning rib respectively received in the at least one positioning slot when the lampshade is assembled to the heat dissipation structure to cover the LED light source.

5. The LED lamp as recited in claim 1, further comprising:
a shell, wherein the shell and the heat dissipation structure include at least one positioning rib and at least one positioning slot in which the at least one positioning rib is respectively received.

6. The LED lamp as recited in claim 1, further comprising:
a shell that includes at least one positioning slot, wherein the driver includes a circuit board having one or more edges respectively received in the at least one positioning slot of the shell.

7. The LED lamp as recited in claim 6, wherein the driver further comprises at least one terminal that is electrically coupled to the circuit board and not coplanar with the circuit board, wherein the circuit board is electrically coupled to the extended portion of the driver, wherein the shell includes at least one opening through which the at least one terminal penetrates the shell.

8. A light emitting diode (LED) lamp, comprising:
a heat dissipation structure that includes a plurality of openings;
an LED light source coupled to the heat dissipation structure and including a plurality of electrodes;
a shell assembled to the heat dissipation structure; and
a driver disposed in the shell and including a plurality of extended portions, the LED light source and the driver disposed on two opposing sides of the heat dissipation structure, the plurality of extended portions respectively penetrating through the plurality of openings such that the extended portions extend toward the LED light source and are electrically coupled to the electrodes.

9. The LED lamp as recited in claim 8, wherein the heat dissipation structure includes a surface and a protrusion connected to the surface, wherein the LED light source includes a bottom surface that comprises a central portion and a peripheral portion such that the central portion is in contact with the protrusion and that the electrodes are disposed on the peripheral portion and spaced apart from the surface of the heat dissipation structure.

10. The LED lamp as recited in claim 8, wherein the heat dissipation structure includes a reception slot in which the LED light source is disposed.

11. The LED lamp as recited in claim 8, further comprising:
a lampshade that includes at least one positioning slot, wherein the heat dissipation structure includes at least one positioning rib respectively received in the at least one positioning slot of the lampshade such that the lampshade is assembled to the heat dissipation structure to cover the LED light source.

12. The LED lamp as recited in claim 8, wherein the shell includes at least one positioning rib and the heat dissipation structure includes at least one positioning slot respectively receiving the at least one positioning rib of the shell.

13. The LED lamp as recited in claim 8, wherein the shell includes at least one positioning slot, and wherein the driver includes a circuit board having one or more edges respectively received in the at least one positioning slot of the shell.

14. The LED lamp as recited in claim 13, wherein the driver further includes a plurality of terminals that are electrically coupled to and not coplanar with the circuit board, wherein the circuit board is electrically coupled to at least some of the extended portions, and wherein the shell includes a plurality of openings such that the terminals extend out of the shell through the openings of the shell.

15. A method of assembling a light emitting diode (LED) lamp, comprising:
providing a heat dissipation structure that includes a plurality of openings, a surface, and a protrusion connected to the surface;
providing an LED light source that includes a bottom surface and a plurality of electrodes, the bottom surface comprising a central portion and a peripheral portion with the electrodes disposed on the peripheral portion;
connecting the central portion of the LED light source to the protrusion of the heat dissipation structure such that the electrodes are spaced apart from the surface of the heat dissipation structure;
providing a shell;
disposing a driver, that includes a plurality of extended portions, inside the shell; and
assembling the shell to the heat dissipation structure such that:
the LED light source and the driver are disposed on two opposing sides of the heat dissipation structure, and
the extended portions are electrically coupled to the electrodes of the LED light source by penetrating through the openings of the heat dissipation structure.

16. The method as recited in claim 15, further comprising:
providing a lampshade; and
assembling the lampshade to the heat dissipation structure such that the lampshade covers the LED light source.

17. The method as recited in claim 16, wherein the heat dissipation structure includes at least one positioning rib, wherein the lampshade includes at least one positioning slot, and wherein assembling the lampshade to the heat dissipation structure comprises the at least one positioning slot of the lampshade respectively receiving the at least one positioning rib of the heat dissipation structure when the lampshade is assembled to the heat dissipation structure.

18. The method as recited in claim 15, wherein the shell includes at least one positioning rib, wherein the heat dissipation structure includes at least one positioning slot, and wherein assembling the shell to the heat dissipation structure comprises the at least one positioning slot of the heat dissipation structure respectively receiving the at least one positioning rib of the shell when the shell is assembled to the heat dissipation structure.

19. The method as recited in claim 15, wherein the shell includes at least one positioning slot, wherein the driver includes a circuit board, and wherein disposing the driver inside the shell comprises respectively receiving one or more edges of the circuit board of the driver in the at least one positioning slot of the shell.

20. The method as recited in claim 19, wherein the driver further includes a plurality of terminals that are electrically coupled to and not coplanar with the circuit board, wherein the circuit board is electrically coupled to the extended portions, wherein the shell includes a plurality of openings, and wherein disposing the driver inside the shell comprises extending the terminals out of the shell through the openings of the shell.
